(19) United States
(12) Patent Application Publication
(10) Pub. No.: US 2025/0385133 A1
(43) Pub. Date: Dec. 18, 2025

(54) METHOD FOR SELECTIVELY DEPOSITING ETCH STOP LAYER

(71) Applicant: Tokyo Electron Limited, Tokyo (JP)

(72) Inventor: Jack Rogers, Nirasaki City (JP)

(21) Appl. No.: 18/745,109

(22) Filed: Jun. 17, 2024

(51) Int. Cl. H01L 21/768; H01L 21/02; H01L 21/311

(52) U.S. Cl. CPC H01L 21/76879; H01L 21/0228; H01L 21/31144; H01L 21/76802; H01L 21/76831

(57) ABSTRACT

A method for making a semiconductor device can include providing an intermediate structure including a first dielectric layer, the first dielectric layer having a first via hole formed therein, where the first via hole opens to an underlying metal contact, forming a first metal via in the first via hole, selectively depositing a first self-assembled monolayer (SAM) on the first metal via, selectively depositing a first etch stop layer on the first dielectric layer, and removing the first SAM to expose the first metal via.

### TECHNICAL FIELD

The present disclosure relates generally to methods for manufacturing semiconductor devices, and more particularly, protecting a dielectric layer during metal etching in a method for manufacturing semiconductor devices.

### BACKGROUND

An integrated circuit contains various semiconductor devices and a plurality of conducting metal paths that provide electrical power to the semiconductor devices and allow the semiconductor devices to share and exchange information. Within the integrated circuit, metal layers are stacked on top of one another using intermetal and interlayer dielectric layers (ILDs) that insulate the metal layers from each other.

Normally, each metal layer must form an electrical contact to at least one additional metal layer. Such electrical contact is achieved by etching a feature (i.e., a via) in the interlayer dielectric layer that separates the metal layers, and filling the resulting via with a metal to create an interconnect. A “via” normally refers to any feature such as a hole, line, or other similar feature formed within a dielectric layer and filled with a metal plug that provides an electrical connection through the dielectric layer to a conductive layer underlying the dielectric layer. Similarly, metal layers connecting two or more vias are normally referred to as “trenches.”

An increase in device performance is normally accompanied by a decrease in device area or an increase in device density. An increase in device density requires a decrease in via dimensions used to form interconnects, including a larger aspect ratio (i.e., depth to width ratio). With larger aspect ratios, a problem of not sufficiently filling a via hole or trench line can result in voids formed in the conducting metal layer. Such voids can create unwanted electrical characteristics, such as increased resistance or even an open circuit failure.

### SUMMARY

In accordance with an embodiment of the present disclosure, a method for making a semiconductor device can include: providing an intermediate structure including a first dielectric layer, the first dielectric layer having a first via hole formed therein, where the first via hole opens to an underlying metal contact; forming a first metal via in the first via hole; selectively depositing a first self-assembled monolayer (SAM) on the first metal via; selectively depositing a first etch stop layer on the first dielectric layer; and removing the first SAM to expose the first metal via.

In accordance with an embodiment of the present disclosure, a method for making a semiconductor device can include: providing an intermediate structure including a first dielectric layer, the first dielectric layer having a first via hole formed therein, where the first via hole opens to an underlying metal contact; forming a first metal via in the first via hole; forming a first cap layer on the first metal via; selectively depositing a first self-assembled monolayer (SAM) on the first cap layer; selectively depositing a first etch stop layer on the first dielectric layer; and removing the first SAM to expose the first cap layer.

In accordance with an embodiment of the present disclosure, a method for making a semiconductor device can include: providing an intermediate structure including a first dielectric layer, the first dielectric layer having a first via hole formed therein, where the first via hole opens to an underlying metal contact; conformally depositing a first liner layer in the first via hole; forming a first metal via on the first liner layer in the first via hole; forming a first cap layer on the first metal via; selectively depositing a first self-assembled monolayer (SAM) on the first cap layer; selectively depositing a first etch stop layer on the first dielectric layer; and removing the first SAM to expose the first cap layer.

### BRIEF DESCRIPTION OF THE DRAWINGS

For a more complete understanding of the present disclosure, and the advantages thereof, reference is now made to the following descriptions taken in conjunction with the accompanying drawings, in which:

FIGS. 1 to 8 are cross-section views illustrating intermediate structures of a semiconductor device made using a method according to an embodiment of the present disclosure;

FIG. 9 is a cross-section view illustrating an intermediate structure during a method of making a semiconductor device according to an embodiment of the present disclosure;

FIG. 10 is a cross-section view illustrating an intermediate structure during a method of making a semiconductor device according to an embodiment of the present disclosure;

FIGS. 11 to 15 are cross-section views illustrating intermediate structures of a semiconductor device made using a method according to an embodiment of the present disclosure;

FIG. 16 is a cross-section view illustrating an intermediate structure during a method of making a semiconductor device according to an embodiment of the present disclosure;

FIG. 17 is a cross-section view illustrating an intermediate structure during a method of making a semiconductor device according to an embodiment of the present disclosure;

FIG. 18 is a cross-section view illustrating an intermediate structure during a method of making a semiconductor device according to an embodiment of the present disclosure;

FIGS. 19 to 21 are cross-section views illustrating intermediate structures of a semiconductor device made using a method according to an embodiment of the present disclosure;

FIGS. 22 to 24 are cross-section views illustrating intermediate structures of a semiconductor device made using a method according to an embodiment of the present disclosure;

FIG. 25 is a cross-section view illustrating an intermediate structure during a method of making a semiconductor device according to an embodiment of the present disclosure; and

FIGS. 26-32 illustrate different flow charts of implementing an etch stop layer using a SAM as a blocking layer in accordance with some embodiments of the present disclosure.

### DETAILED DESCRIPTION OF ILLUSTRATIVE EMBODIMENTS

Referring now to the drawings, in which like reference numbers can be used herein to designate like or similar elements throughout the various views, illustrative and example embodiments are shown and described. The figures are not drawn to scale, and in some instances the drawings are exaggerated or simplified in places for illustrative purposes. One of ordinary skill in the art can appreciate many possible applications and variations for other embodiments based on the following illustrative and example embodiments provided in the present disclosure. Some example embodiments of the present disclosure are described below. Other embodiments can also be understood from the entirety of the specification as well as the claims filed herein.

In the present disclosure, terms such as “first”, “second”, and the like, may be used to describe various components, but the components are not necessarily limited by such terms, for example, regarding order, sequence, importance, or number of such components possible in an embodiment. Such terms can be used merely for the purpose of distinguishing one component from other components in a given embodiment or group of embodiments. For example, a first component may be referred to as a second component, and similarly, a second component may also be referred to as a first component without departing from the scope of rights according to the present disclosure.

In the present disclosure and drawings, labels such as “M0”, “M1”, and “M2” can be used to describe various metallization levels in the drawings. However, a labeling of metallization levels in the drawings for describing a given example embodiment of the present disclosure may not correspond to the labels used to name or identify actual metallization levels, or to define an actual vertical location thereof, in an actual implementation of an embodiment. Thus, such labels used in the present specification do not necessarily limit the metallization to actual metallization that implements an embodiment of the present disclosure. For example, a metallization level labeled “M1” in present specification may correspond to an actual metallization level located at or designated as level M5 while still being in accordance with an embodiment of the present disclosure.

The minimum dimension of patterned features can be shrunk periodically to roughly double the component density at each successive technology node, thereby reducing the cost per function. Innovations in patterning, such as immersion deep ultraviolet (i-DUV) lithography, multiple patterning and 13.5 nm wavelength extreme ultraviolet (EUV) optical systems have brought some critical dimensions down a scale less than ten nanometers. This squeezes the margin for pattern misalignment and puts pressure on process integration to prevent electrical opens and shorts in middle-of-line (MOL) and back-end-of-line (BEOL) interconnect elements.

The conventional use of copper as conductive material for vias and/or trenches or conducting lines becomes challenging as device feature sizes continue to scale down because copper requires barrier layers and liners to prevent migration of the copper. As feature sizes for MOL and BEOL interconnect elements continue to scale down, copper-alternatives that do not require barrier layers and liners are being investigated and implemented. However, such copper-alternatives present new issues and problems to tackle, such as different process flows, different etch properties, and minimizing the device contact resistance at joining interfaces of conducting structures, especially for tight metal pitches, and line resistance. Some example metal materials that can be used as copper alternatives are ruthenium (Ru), cobalt (Co), molybdenum (Mo), tungsten (W), and niobium (Nb), for example.

Due to smaller via hole diameters and larger aspect ratios (depth to width ratios) as technology nodes progress (e.g., greater device density and smaller scales for features), voids can form during the filling of via holes with metal material(s) because of incomplete or uneven filling for some via holes. Thus, it is desirable to reduce the aspect ratio as much as possible to make it easier to consistently and reliably fill the via holes completely and evenly with the metal material(s). One way to reduce the aspect ratio is to remove the mask after patterning and etching an intermetal dielectric layer prior to filling the via holes with metal material(s). However, doing so can leave the intermetal dielectric layer exposed later during subsequent etching operations. Hence, there is a need to reduce the aspect ratio by removing the mask layer while also protecting the intermetal dielectric layer later in subsequent etching operations.

A method embodiment of the present disclosure can fulfill this need and solve the above-stated problems by making use of selective deposition of a self-assembled monolayer (SAM) and by selectively depositing an etch stop layer over the intermetal dielectric layer. This etch stop layer can then later protect the intermetal dielectric layer during later etching operations while also providing a stop point for such etching operation. And, the use of SAM provides an efficient way to selectively deposit that etch stop layer in some process integrations.

In some embodiments of the present disclosure, a method for forming a semiconductor device can include: removing a mask from a top surface of a first dielectric layer after forming a first via hole in the first dielectric layer, to expose the top surface of the first dielectric layer; forming a first metal via in a first via hole; selectively depositing a first self-assembled monolayer (SAM) on the first metal via; selectively depositing a first etch stop layer on the first dielectric layer; removing the first SAM to expose the first metal via; forming a second metal layer on the first metal via and the first etch stop layer, where the second metal layer directly contacts the first metal via; and then patterning and etching the second metal layer to form a second metallization layer having multiple distinct conducting lines, where the etching of the second metal layer stops on the first etch stop layer, and where the etching is selective with respect to the first etch stop layer, such that the first etch stop layer protects the underlying first dielectric layer during the etching of the second metal layer.

In some embodiments of the present disclosure, a method for forming a semiconductor device can include: removing a mask from a top surface of a first dielectric layer after forming a first via hole in the first dielectric layer, to expose the top surface of the first dielectric layer; forming a first metal via in a first via hole; forming a first cap layer on the first metal via (e.g., a metal cap layer or a graphene layer); selectively depositing a first SAM on the first cap layer; selectively depositing a first etch stop layer on the first dielectric layer; removing the first SAM to expose the first cap layer; forming a second metal layer on the first cap layer and the first etch stop layer, where the second metal layer directly contacts the first cap layer; and then patterning and etching the second metal layer to form a second metallization layer having multiple distinct conducting lines, where the etching of the second metal layer stops on the first etch stop layer, and where the etching is selective with respect to the first etch stop layer, such that the first etch stop layer protects the underlying first dielectric layer during the etching of the second metal layer.

In some embodiments of the present disclosure, as a variation (likely dependent on the materials selected for the second metallization layer), rather than forming the second metal layer and using subtractive etching of the second metal layer to form the multiple distinct conducting lines, a second dielectric layer can be formed, patterned, and etched to define the trenches for the multiple distinct conducting lines, and then depositing the second metal layer into those trenches, with the other operations of a method according to an embodiment of the present disclosure being the same up to the deposition of the second dielectric layer.

Some embodiments of the present disclosure make use of a self-assembled monolayer (SAM) as a blocking layer. Generally, SAMs are molecular assemblies that can selectively form on certain material surfaces (e.g., metal surfaces for some example embodiments herein) through adsorption, organizing into ordered domains of varying sizes. A SAM typically consists of a molecule with a head group, a tail group, and a functional end group. Formation of a SAM on a certain surface (dependent on the SAM formulation selected for a given surface material) can occur via chemisorption of the head groups from the vapor phase, either at room temperature or above. Subsequently, the tail groups organize slowly. Initially, at low molecular density on the surface, adsorbate molecules may aggregate into a disordered mass or form an ordered two-dimensional “lying down phase.” As the molecular coverage increases, typically over minutes to hours, three-dimensional crystalline or semicrystalline structures can selectively develop on the given certain surfaces. The head groups can assemble directly on the given certain surfaces, while the tail groups can extend away from the given certain surfaces. Examples of head groups for SAMs that can form on metal surfaces include thiolates, metal-coordinating ligands, phosphines, amine groups, any suitable hydro-carbon SAM material, or any suitable combination thereof. Some specific examples of SAMs will be described below herein.

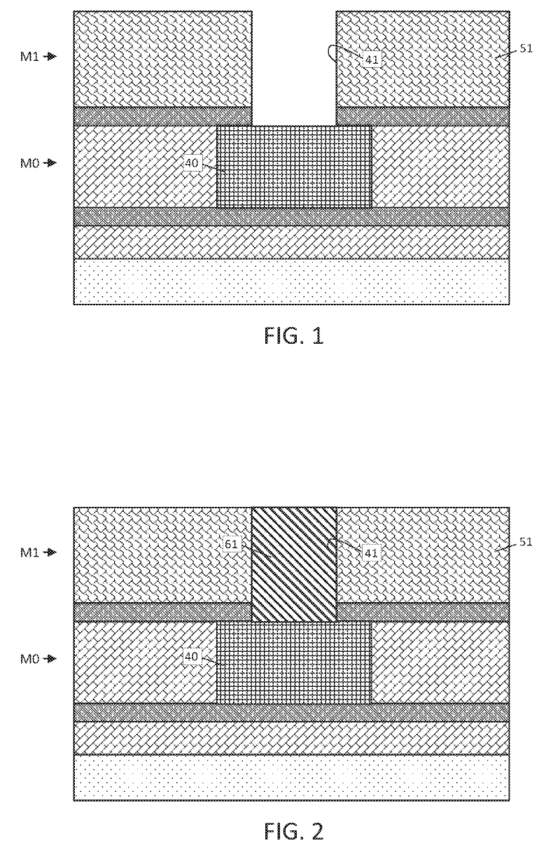

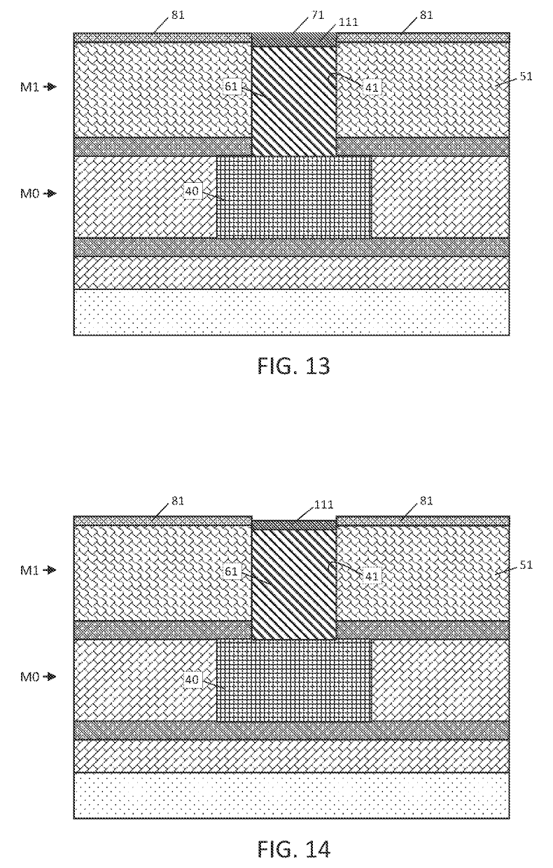

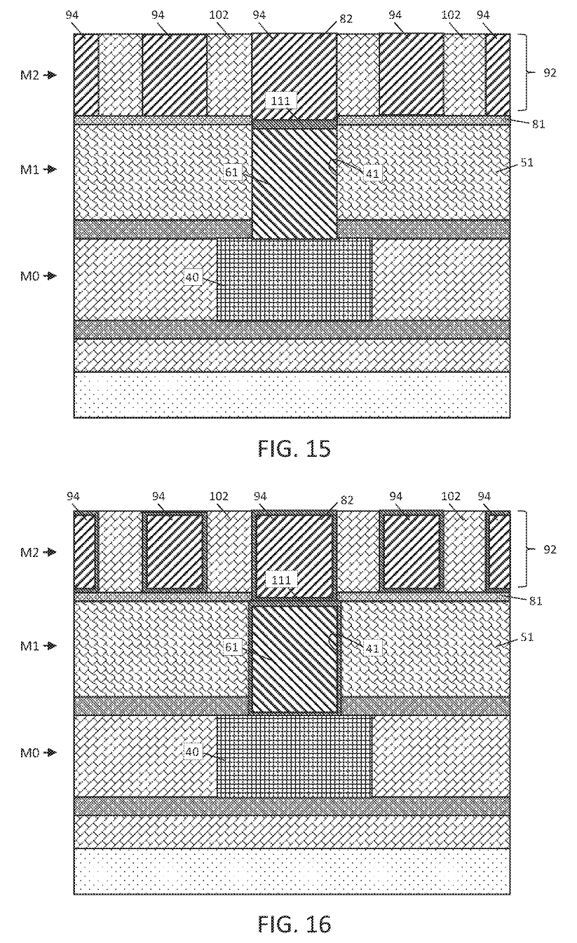

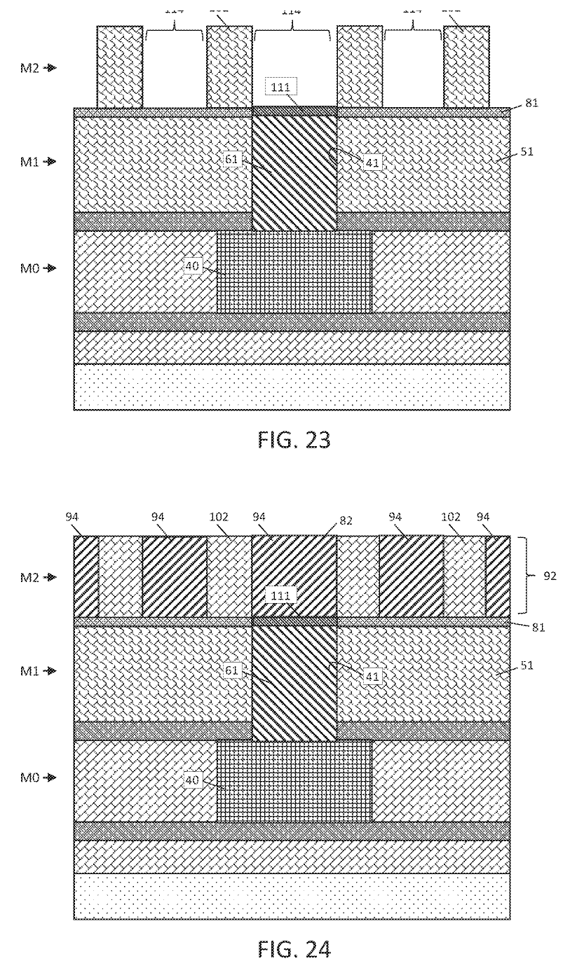

FIGS. 1-25 are various cross-section views illustrating various intermediate structures during various methods of making a semiconductor device according to some example embodiments of the present disclosure. For simplification and illustration purposes, FIGS. 1-25 are merely showing some portions of a semiconductor device as intermediate structures that can be relevant to a method of making the semiconductor device according to an example embodiment of the present disclosure. For example, in FIGS. 1-25, to simplify the drawings, as can be readily understood by one of ordinary skill in the pertinent art, additional layers and structures of a semiconductor device made before, under, below, or adjacent to the intermediate structures shown in the drawings are omitted, which can include any structures, types, and circuits of semiconductor devices, such as additional interconnects, additional vias, additional trenches, additional interlayer dielectric layers, additional intermetal dielectric layers, additional backend-of-line (BEOL) stage(s) or level(s), frontend-of-line (FEOL) stages or levels, transistors, diodes, capacitors, resistors, inductors, integrated circuits, memory cells, logic, processor portions, digital devices, analog devices, semiconductor wafer, silicon-on-insulator wafer, or combinations thereof, for example. Also in FIGS. 1-25, to simplify the drawings, as can be readily understood by one of ordinary skill in the pertinent art, additional layers and structures of a substrate for a semiconductor device made after, over, above, or adjacent to the intermediate structures shown in the drawings are omitted, which can include any structures, types, and circuits of semiconductor devices, such as additional interconnects, additional vias, additional trenches, additional interlayer dielectric layers, additional intermetal dielectric layers, additional backend-of-line (BEOL) stage(s) or level(s), passivation layers, contact pads, local interconnects, global interconnects, wire bonding, packaging, or combinations thereof, for example. Furthermore, in an actual completed semiconductor device cross-section, the intermediate structures, which are illustrated and represented in the drawings of the present disclosure in a simplified manner as having squared edges and/or linear shapes, can be actually more rounded, have rounded corners, more curved shaped, and less linear shaped, and can be perhaps even difficult to visually see even in an image taken with a scanning electron microscope (SEM) or a transmission electron microscope (TEM) due the extremely small size, thickness, and scale of some layers and resulting features (e.g., some on the scale of atoms to less than 5 nanometers in size), or may be removed during processing and little or no remnants of certain layers, features, or portions in the final semiconductor device publicly sold and used.

FIGS. 1 to 8 are cross-section views illustrating intermediate structures having metallization levels M0-M2 of a semiconductor device made using a method including the use of a SAM for selectively forming a protective etch stop layer in a semi-damascene integration flow, according to an embodiment of the present disclosure. Referring to FIG. 1, an intermediate structure can include a metal contact 40 or non-copper-containing metal layer, such as a tungsten metal contact or metallization interconnect at a base interconnect level M0 of the intermetal and interlayer dielectric layers (e.g., a “zero” level), a first via hole 41 formed in a first dielectric layer 51 at level M1, for example. In other embodiments, the underlying metal contact 40 can be any conducting/metal structure/feature, and a potential embodiment is not necessarily limited to the underlying metal contact being an M0 level tungsten contact, for example. The intermediate structure of FIG. 1 is simple one example embodiment for illustration purposes.

Still referring to FIG. 1, the intermediate structure can be after the patterning and etching to form the first via hole 41, and after mask material(s)/layer(s) are removed, with the first via hole 41 being open to the underlying metal contact 40 and ready to be filled with conducting material(s) for forming the first via. As noted above, it can be preferred to remove the mask(s) after the patterning and etching of the first via hole 41 to reduce or minimize the aspect ratio and improve the process for consistently filling or selectively depositing metal into the first via hole 41, with a goal of avoiding the formation of voids in the first via metal. The mask(s) can be removed by a wet clean, for example. An oxide hard mask can be removed using a diluted hydrofluoric acid (DHF), for example. The process used to remove the mask(s) from the first dielectric layer 51 can depend on the material(s) used for the mask(s) and the first dielectric layer, to avoid damaging the first dielectric during the removal of the mask(s).

In some embodiments, the first dielectric layer 51 can have a thickness in a range of 30 nm to 100 nm, while the first via hole 41 can have a critical dimension (e.g., diameter) in a range of 5 nm to 20 nm, which can be a relatively high aspect ratio via hole. For example, in some embodiments, the first dielectric layer 51 can have a thickness of about 60 nm and the first via hole 41 can have a diameter of about 10 nm.

In some embodiments, the first dielectric layer 51 can be a single layer of one material, a single layer of a mix of multiple materials, multiple layers of one material, multiple layers of a same material or mix of multiple materials, or multiple layers of different materials, for example. In some embodiments, the material(s) of a given first dielectric layer 51 can be selected to in view of providing acceptable dielectric properties (e.g., low-k), and fitting within the process integration flow and device electrical characteristics (e.g., thermal budgets, stress inducing, non-stress inducing, thermal stress mismatching, adhesion, electrical properties, parasitic capacitance, etc.). In some embodiments, such material(s) of a given first dielectric layer 51 can include low-k dielectric material, such as a suitable silicon dioxide (SiO₂) and structural variations thereof (e.g., flowable oxide, gel, including large air pockets, porous, etc.), silicon carbonitride (SiCN), silicon oxycarbide (SiOC), silicon oxycarbonitride (SiOCN), silicon oxynitride (SiON), silicon nitride (SiN), layers thereof, mixtures thereof, laminates thereof, or generally any combination thereof, for example.

Referring to FIG. 2, the first via hole 41 is filled or mostly filled with metal material to form a first metal via 61. This can be a single damascene via fill operation and/or a selective via fill operation, for example. In some embodiments, the first via hole 41 need not be completely filled to the top surface of the first dielectric layer 51 (e.g., because another subsequent metal layer will be formed on it that can complete the filling of the first via hole 41 and still make sufficient electrical contact with the first metal via 61).

Even though the first metal via 61 is illustrated and represented in the drawings as a single layer of one material, in some embodiments, this first metal via 61 can be a single layer of one material, a single layer of an alloy or mix of multiple materials, multiple layers of one material, multiple layers of a same alloy or mix of multiple materials, or multiple layers of different materials or alloy(s) of materials, for example. In some embodiments, the material(s) of a given first metal via 61 can be selected in view of providing acceptable low electrical resistance for the multilevel metallization interconnects. In some embodiments, such metal material(s) of a given first metal via 61 can include ruthenium, molybdenum, niobium, tungsten, tantalum, aluminum, alloys thereof, layers thereof, mixtures thereof, laminates thereof, or generally any combination thereof, for example. By using materials such as ruthenium and/or molybdenum, the use of a barrier layer can be omitted. However, while the use of ruthenium and/or molybdenum can be desirable for filling smaller diameter and/or higher aspect ratio via holes because a barrier layer or liner layer can be omitted, other issues in the process flow using such materials arise, such as oxidation and interface resistance, which can introduce additional processing steps and intervening layers (discussed more below).

In some embodiments, the first metal via 61 can be formed using physical vapor deposition (PVD), plasma enhanced physical vapor deposition (PEPVD), chemical vapor deposition (CVD), plasma enhanced chemical vapor deposition (PECVD), atomic layer deposition (ALD), or any combination thereof, for example. For example, to selectively fill the first via hole 41 with the material(s) of the first metal via 61, and taking into account the aspect ratio and opening size of the first via hole 41, a CVD, PECVD, or ALD may be performed first (e.g., bottom-up conformal fill type operation) and then a PEPVD or PVD may be performed secondly to complete the selective filling of the first via hole 41 because a CVD or ALD type filling may be too slow compared to a PVD type filling. And, as noted above, copper-alternative materials that do not require a barrier layer, such as ruthenium or molybdenum, can be used to more easily fill a high aspect ratio via hole without the need for complex multi-layer structures having liners and/or barrier layers, for example.

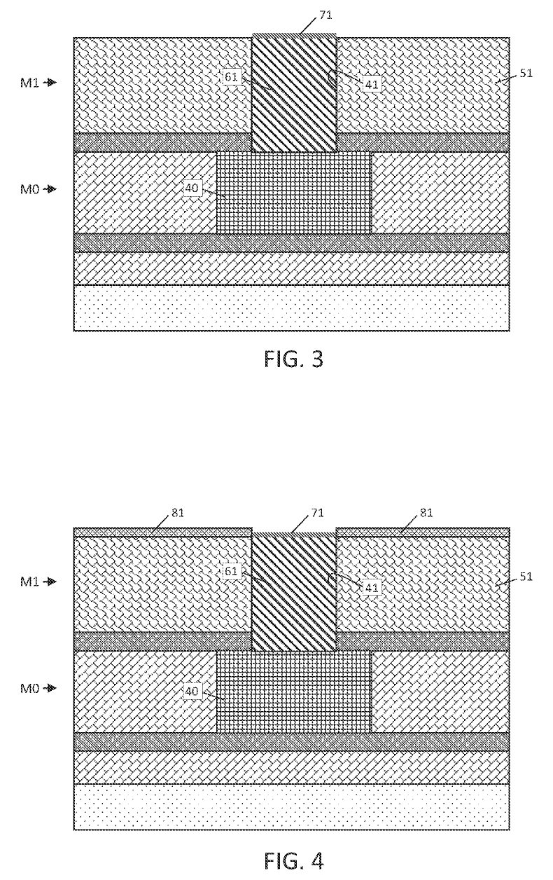

Referring to FIG. 3, a first SAM 71 is selectively deposited on the first metal via 61. The material and the deposition/formation process selected for the first SAM 71 can depend on the top-most material or exposed material of the first metal via 61, and the top-most material or exposed material of the first dielectric layer 51. The first SAM 71 can be selected to adhere to or bond to the first metal via 61 substantially faster and/or stronger than to the first dielectric layer 51, thereby providing a selective deposition of the first SAM 71 on the first metal via 61.

A thickness of the first SAM 71 (to be sufficient as a blocking layer) can be a small as a single monolayer, in a range of 1 nm to 3 nm, and can be typically about 1 nm to 2 nm, depending on the specific molecules used in the SAM and their packing density. Generally, the thickness of a SAM can be determined by the length of the molecules that make up the monolayer and the orientation they adopt on the surface.

As noted above, some examples of head groups for SAMs that can form on metal surfaces include thiolates, metal-coordinating ligands, phosphines, amine groups, any suitable hydro-carbon SAM, or any suitable combination thereof. Next, some more specific examples of SAMs will be described.

Some example thiolates that can be suitable for chemisorption of the thiol (-SH) group onto metal atoms, interaction with metal atoms, and/or relatively stronger bonding with metal atoms relative to dielectric materials, for potential use in some embodiments, can include: alkanethiols (e.g., octanethiol; dodecanethiol) (e.g., for copper and cobalt); dithiol compounds (e.g., 1,8-octanedithiol (ODT); 1,2-ethanedithiol (EDT)) (e.g., for ruthenium); phosphonothiols, (e.g., hexanethiolphosphonic acid (HPTA)) (these molecules can contain both thiol and phosphonic acid groups, which can facilitate relatively stronger bonding and enable effective chemisorption onto metal surfaces) (e.g., for molybdenum and tungsten); or any suitable combination thereof.

Some example metal-coordinating ligands that can be suitable for interaction with metal atoms and/or relatively stronger bonding with metal atoms relative to dielectric materials, for potential use in some embodiments, can include: 1,10-phenanthroline (e.g., bidentate ligand) (e.g., for copper); 2,2'-bipyridine (e.g., bidentate ligand) (e.g., for cobalt); tris (2,2'-bipyridine) ruthenium(II) (Ru(bpy)3^2+) (e.g., bipyridine ligand) (e.g., for ruthenium); dimethylglyoxime (e.g., for molybdenum); tungsten hexacarbonyl (W(CO)₆) (e.g., six carbonyl (CO) ligands coordinated to a tungsten atom) (e.g., for tungsten); or any suitable combination thereof.

Some example phosphines (e.g., phosphine ligands) that can be suitable for interaction with metal atoms and/or relatively stronger bonding with metal atoms relative to dielectric materials, for potential use in some embodiments, can include: triphenylphosphine (PPh3) (e.g., for copper); tris (2-diphenylphosphinoethyl) amine (PNP) (e.g., for cobalt); tris (2-diphenylphosphinoethyl) phosphine (TPP) (e.g., for ruthenium); diphenylphosphinoethane (dppe) (e.g., bidentate phosphine ligand) (e.g., for molybdenum); and tris (tert-butyl) phosphine (tBu3P) (e.g., for tungsten); or any suitable combination thereof.

Some example amine groups (e.g., amine-containing ligands) that can be suitable for interaction with metal atoms and/or relatively stronger bonding with metal atoms relative to dielectric materials, for potential use in some embodiments, can include: diethylenetriamine (DETA) (e.g., polyamine ligand) (e.g., for copper); 1,4,8,11-tetraazacyclotetradecane (cyclam) (e.g., macrocyclic polyamine ligand) (e.g., for cobalt); 2,2'-Bipyridine (bipy) (e.g., for ruthenium); triethylenetetramine (TETA) (e.g., polyamine ligand) (e.g., for molybdenum); N,N-Dimethylethylenediamine (DMEDA) (e.g., diamine ligand) (e.g., for tungsten); or any suitable combination thereof.

Referring to FIG. 4, a first etch stop layer 81 is selectively deposited on the first dielectric layer 51. The first SAM 71 on the first metal via 61 can act as a blocking layer to protect the first metal via 61 while depositing the first etch stop layer 81.

Even though the first etch stop layer 81 is illustrated and represented in the drawings as a single layer of one material, in some embodiments, this first etch stop layer 81 can be a single layer of one material, a single layer of a mix of multiple materials, multiple layers of one material, multiple layers of a same material or mix of multiple materials, or multiple layers of different materials, for example. In some embodiments, the material(s) of a given first etch stop layer 81 can be selected to in view of providing an insulating layer and providing acceptable etch selectivity with respect to subsequently formed conducting lines, compatibility with the first dielectric layer, and fitting within the process integration flow and device electrical characteristics (e.g., thermal budgets, stress inducing, non-stress inducing, thermal stress mismatching, adhesion, electrical properties, parasitic capacitance, etc.). In some embodiments, such material(s) of a given first etch stop layer 81 can include low-k dielectric material, such as silicon carbonitride (SiCN), silicon oxycarbide (SiOC), silicon oxycarbonitride (SiOCN), silicon oxynitride (SiON), silicon nitride (SiN), silicon carbide (SiC), layers thereof, mixtures thereof, laminates thereof, or generally any combination thereof, for example. In some embodiments, such material(s) of a given first etch stop layer 81 can include metal oxide dielectric material, such as aluminum oxide (Al₂O₃), hafnium oxide (HfO₂), titanium oxide (TiO₂), tantalum oxide (Ta₂O₅), tungsten oxide (WO₃), layers thereof, alloys thereof, mixtures thereof, laminates thereof, or generally any combination thereof, for example. In some embodiments, such material(s) of a given first etch stop layer 81 can include metal nitride material, such as aluminum nitride (AlN), copper nitride (Cu₃N₂), manganese nitride (MnN or Mn₄N), layers thereof, alloys thereof, mixtures thereof, laminates thereof, or generally any combination thereof, for example.

In some embodiments, the first etch stop layer 81 can be formed using physical vapor deposition (PVD), plasma enhanced physical vapor deposition (PEPVD), chemical vapor deposition (CVD), plasma enhanced chemical vapor deposition (PECVD), atomic layer deposition (ALD), or any combination thereof, for example. The selection of the deposition operation used for depositing the first etch stop layer 81 can take into account compatibility with and interaction with the first SAM 71, to ensure that the first SAM 71 performs its role of blocking the first etch stop layer 81 from permanently forming or adhering to the first metal via 61, for example. For example, during the deposition of the first etch stop layer 81, the deposition can proceed rapidly on the dielectric material of the first dielectric layer 51 but can be hindered by the blocking layer properties of the first SAM 71. With such deposition selectivity of the material of the first etch stop layer 81 on the first dielectric layer 51 relative to the first SAM 71, and because the first etch stop layer 81 typically will be relatively thin (e.g., about 3 nm), the selective deposition of the first etch stop layer 81 can mostly form on the first dielectric layer 51 to a sufficient/desired thickness while only a negligible, minimal, or almost no amount of the first etch stop layer 81 is deposited on the first SAM 71. Also, the selection of the deposition operation used for depositing the first etch stop layer 81 can take into account the tools available or already in use for previous and/or subsequent operations of the process integration flow.

In some embodiments, the first etch stop layer 81 can be formed with a minimum thickness that will provide protection for the first dielectric layer 51 during subsequent etching of conducting lines and/or that will act as a sufficient etch stop point for subsequent etching of conducting lines, to ensure that the formation of the first etch stop layer 81 does not form on the first metal via 61 and does not reduce the surface contact conductivity of the first metal via 61 with a subsequently formed conducting line (i.e., preventing increased resistance or capacitance forming at the top surface of the first metal via 61). For example, the first etch stop layer 81 can have a thickness in a range of 1 nm to 10 nm. In some embodiments, the first etch stop layer 81 can be a silicon carbonitride (SiCN) layer having a thickness of about 3 nm, for example.

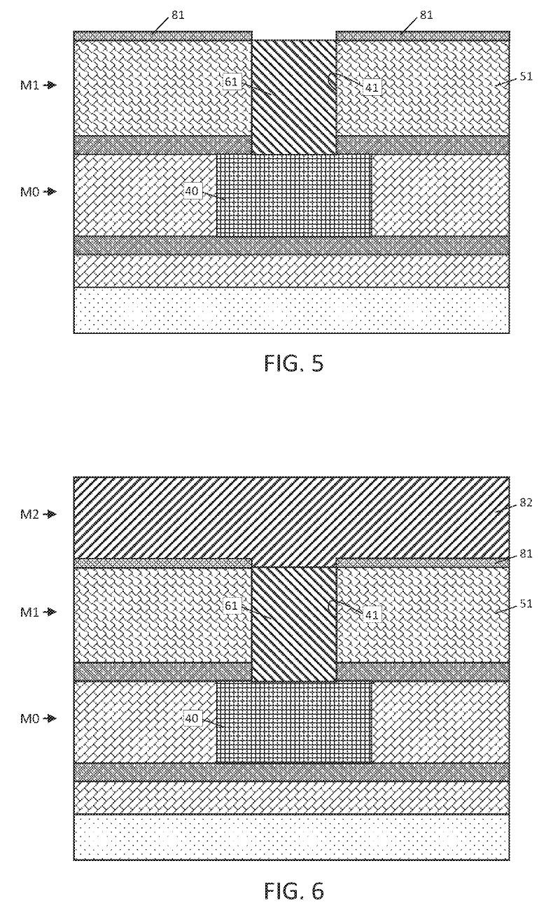

Referring to FIG. 5, the first SAM 71 can be removed, which also removes materials of the first etch stop layer (if any) that may have deposited on the first SAM. Because the material of the first etch stop layer 81 does not adhere well to or does not bond with the first SAM 71, the first SAM 71 provides a barrier or blocking layer to prevent the first etch stop layer 81 from forming directly on the first metal via 61. The removal of the first SAM 71 then exposes the first metal via 61 while leaving the first etch stop layer 81 on and covering/shielding the first dielectric layer 51, which effectively provides a selective deposition of the first etch stop layer 81 on the first dielectric layer 51 while keeping the first metal via 61 open and ready for electrical contact with a subsequently formed electrical conducting line, trench, or via.

The first SAM 71 can be removed by one or more treatments to each remove part of, most of, or all of the first SAM 71. In some embodiments, such treatment to remove the first SAM 71 can include a heat-treating step that desorbs the exposed blocking layer from the intermediate structure, for example.

Referring to FIG. 6, a second metal layer 82 is formed on the first metal via 61 and the first etch stop layer 81. This can be an overburden fill of metal and/or blanket deposition of metal at level M2. For this example process flow, the second metal layer 82 can be a metal capable of or compatible with subtractive etching, such as ruthenium (Ru) or molybdenum (Mo), for example.

Even though the second metal layer 82 is illustrated and represented in the drawings as a single layer of one material, in some embodiments, this second metal layer 82 can be a single layer of one material, a single layer of an alloy or mix of multiple materials, multiple layers of one material, multiple layers of a same alloy or mix of multiple materials, or multiple layers of different materials or alloy(s) of materials, for example. In some embodiments, the material(s) of a given second metal layer 82 can be selected in view of providing acceptable low electrical resistance for the multilevel metallization interconnects. In some embodiments, such metal material(s) of a given second metal layer 82 can include copper alternatives, such as ruthenium, molybdenum, niobium, tungsten, tantalum, aluminum, alloys thereof, layers thereof, mixtures thereof, laminates thereof, or generally any combination thereof, for example.

In some embodiments, the second metal layer 82 can be formed using physical vapor deposition (PVD), plasma enhanced physical vapor deposition (PEPVD), chemical vapor deposition (CVD), plasma enhanced chemical vapor deposition (PECVD), atomic layer deposition (ALD), or any combination thereof, for example. For example, if the top surface of the first metal via 61 is not planar with the top surface of the first etch stop layer 81 (e.g., first metal via 61 being recessed relative to the first etch stop layer 81 and/or the first dielectric layer 51, and/or if the top surface of the first metal via 61 is irregular, convex, concave, or non-planar, a CVD, PECVD, or ALD may be performed first (e.g., conformal fill type operation) and then a PEPVD or PVD may be performed secondly to complete the deposition of the second metal layer 82 because a CVD or ALD type filling can be too slow compared to a PVD type deposition. It can be a critical specification and requirement that the second metal layer 82 is fully contacting the top surface of the first metal via 61, without gaps, voids, or delamination, to maximize the electrical contact and minimize the contact resistance between the first metal via 61 and the second metal layer 82.

In some embodiments, the second metal layer 82 can be a different material than the first metal via 61. In some embodiments, the second metal layer 82 can have a thickness in a range of 20 nm to 100 nm. In some embodiments, the second metal layer 82 can have a thickness in a range of 100 nm to 200 nm. In some embodiments, the second metal layer 82 can be ruthenium or molybdenum having a thickness of about 30 nm, for example.

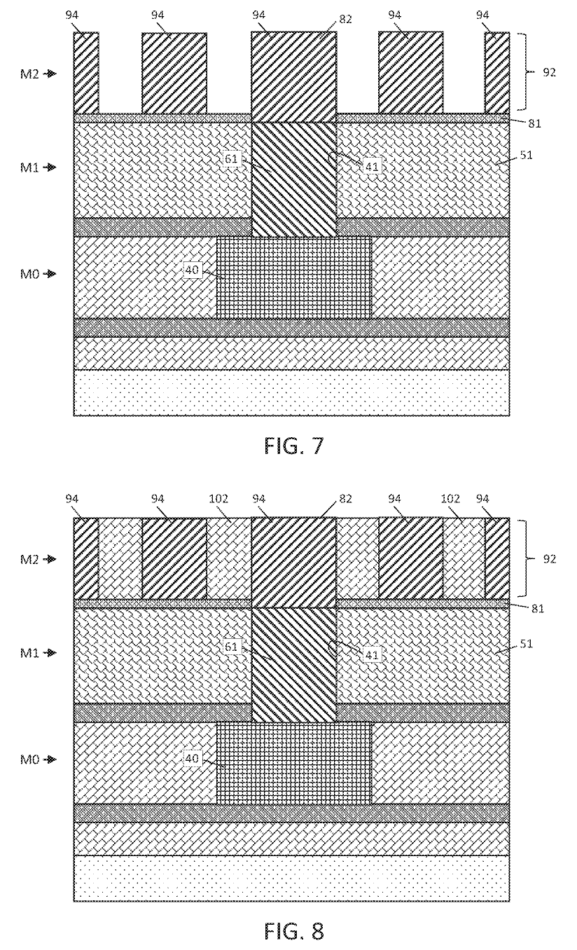

Referring to FIG. 7, the second metal layer 82 can be patterned and etched to form a second metallization layer 92 (at level M2 in this example) including multiple distinct conducting lines 94. Accordingly, there can be electrical connection to the first metal via 61 and there can be open areas between and separating the multiple conducting lines 94. The etching of the second metal layer 82 can stop on the first etch stop layer 81 (i.e., can open to the first etch stop layer 81). The etching of the second metal layer 82 can be selective to etch the second metal layer 82 faster than the first etch stop layer 81, which can help with fully opening up the bottoms of the open areas and fully separating (physically and electrically) the multiple conducting lines 94 as needed and per design/specifications. Photolithography and patterning masks can be used and removed between the intermediate structures of FIGS. 6 and 7, as can be apparent to one of ordinary skill in the art, and thus are not further described herein.

Without the first etch stop layer 81 being in place, there would be a much greater potential for damaging the first dielectric layer 51 (especially when it is a low-k dielectric material) while etching the second metal layer 82 at level M2 and/or undercutting the pattern of the multiple conducting lines 94 during the wet cleaning after the etching of the second metal layer 82, which could cause structural integrity problems for supporting and stabilizing the conducting lines 94 formed in the second metal layer 82 (and which thereby could lead to electrical characteristic problems or shorts between district conducting lines 94 that are supposed to remain separated). The first etch stop layer 81 can act as a stable structural platform or subfloor (uniformly supported by the underlying first dielectric layer 51) for the multiple distinct conducting lines 94 formed in the second metal layer 82 by the etching, which can improve device reliability, process integration flow, manufacturing consistency, manufacturing repeatability, and product yield.

In a completed structure of a semiconductor device made according to an embodiment of the present disclosure, portions of the first etch stop layer 81 can be removed (e.g., over etching while etching the second metal layer 82) in some places, and all of or portions of the first etch stop layer 81 can remain (e.g., between the first dielectric layer 51 and the second metallization layer 92).

Referring to FIG. 8, a second dielectric layer 102 can be formed between the multiple distinct conducting lines 94 of the second metallization layer 92. For example, a low-k dielectric material, such as a suitable silicon dioxide and structural variations thereof, can be used for the second dielectric layer 102. In some embodiments, by using materials such as ruthenium and/or molybdenum, the use of a barrier layer and/or liner layer can be omitted (i.e., the second dielectric layer 102 can be directly on the conducting lines 94 of the second metallization layer 92). After depositing the second dielectric layer 102, overburden or overfill materials can be removed while planarizing (e.g., using chemical mechanical polishing (CMP)) the top surface of the intermediate structure shown in FIG. 8, as can be apparent to one of ordinary skill in the art (and thus is not further described herein).

Even though the second dielectric layer 102 is illustrated and represented in the drawings as a single layer of one material, in some embodiments, in some embodiments, the second dielectric layer 102 can be a single layer of one material, a single layer of a mix of multiple materials, multiple layers of one material, multiple layers of a same material or mix of multiple materials, or multiple layers of different materials, for example. In some embodiments, the material(s) of a given second dielectric layer 102 can be selected to in view of providing acceptable dielectric properties (e.g., low-k), and fitting within the process integration flow and device electrical characteristics (e.g., thermal budgets, stress inducing, non-stress inducing, thermal stress mismatching, adhesion, electrical properties, parasitic capacitance, etc.). In some embodiments, such material(s) of a given second dielectric layer 102 can include low-k dielectric material(s), such as any suitable silicon dioxide (SiO₂) and structural variations thereof (e.g., flowable oxide, gel, including large air pockets, porous, etc.), silicon carbonitride (SiCN), silicon oxycarbide (SiOC), silicon oxycarbonitride (SiOCN), silicon oxynitride (SiON), silicon nitride (SiN), layers thereof, mixtures thereof, laminates thereof, or generally any combination thereof, for example.

In some embodiments, the operation of forming the second dielectric layer 102 can be omitted or varied because an air gap may remain between the conducting lines 94 shown in FIG. 7, where the air gap acts as the low-k dielectric between the conducting lines 94. For example, the second dielectric layer 102 may be initially formed and then partially, mostly, or completely evaporated after another/subsequent layer is formed over the intermediate structure of FIG. 8.

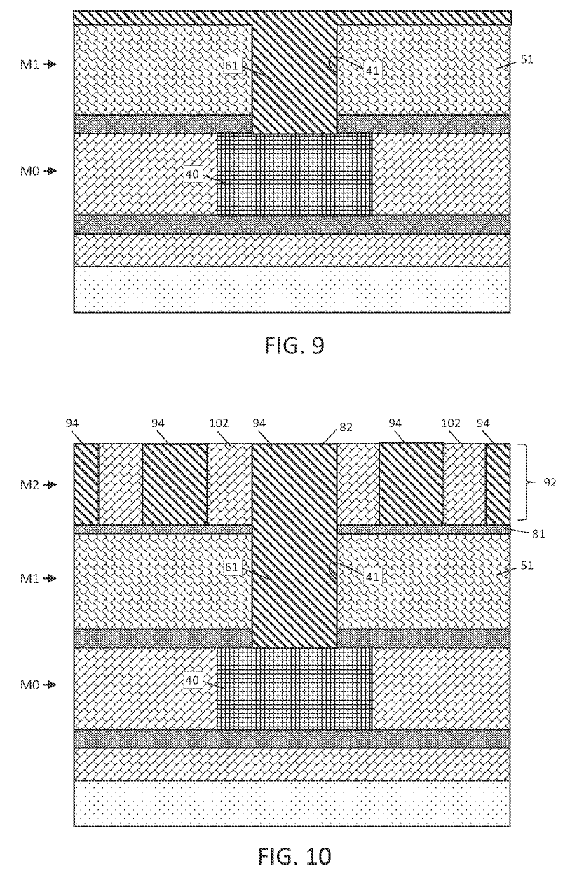

Referring to FIG. 9, while filling the first via hole 41 with material(s) to form the first metal via 61 between FIGS. 1 and 2, the first via hole 41 can be overfilled, resulting in what is sometimes referred to as an overburden fill. In such case, the extra materials of the first metal via 61 that are formed on the top surface of the first dielectric layer 51 can be removed (e.g., using CMP) to planarize the top surface of the first metal via 61 with the top surface of the first dielectric layer 51 (e.g., as illustrated in FIG. 2), or to substantially planarize them (e.g., the material of the first dielectric layer 51, such as low-k dielectric material, can be removed faster than the material of first metal via 61, such as metal) (e.g., the top of the first metal via 61 can be higher than some top of portions of the first dielectric layer 51 in an actual device).

Referring to FIG. 10, in some embodiments the second metal layer 82 can be a same material as the first metal via 61. In such case, after the formation of the second metal layer 82, it can be difficult or impossible to see a dividing line between a top of the first metal via 61 and a bottom of the second metal layer 82 at the contact interface, as illustrated in FIG. 10.

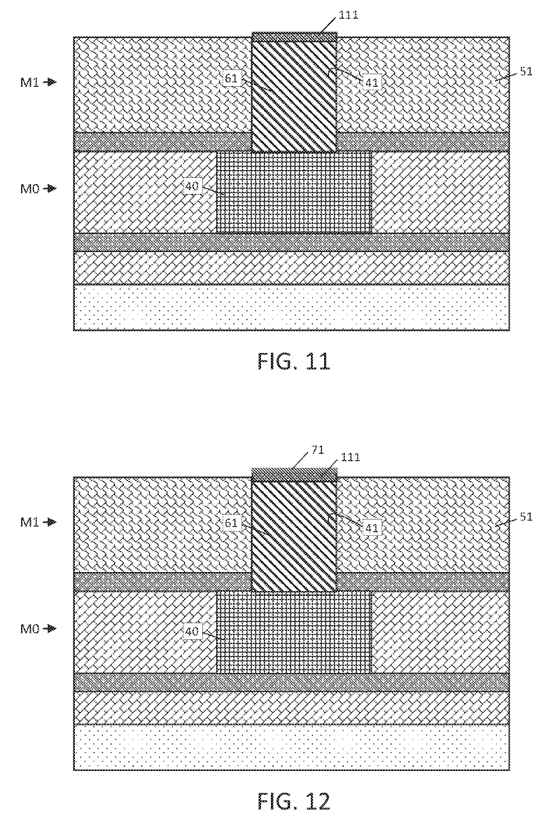

FIGS. 11 to 15 are cross-section views illustrating intermediate structures of a semiconductor device made using a method according to an embodiment of the present disclosure. Referring to FIG. 11, after the intermediate structure of FIG. 2 or similar to it (e.g., the first metal via 61 can be underfilled or not completely filled), a first cap layer 111 can be formed on the first metal via 61.

For example, in some cases when the material(s) of the second metal layer 82 are different than the material(s) of the first metal via 61, the first cap layer 111 can be inserted therebetween. The first cap layer 111 can act as a barrier layer to prevent diffusion and/or intermixing of materials to/from the second metal layer 82 from/to the first metal via 61, such as during subsequent processing steps at elevated temperatures (e.g., heat-treating and/or annealing steps at or above 400ºC) and/or during operation of the completed semiconductor device generating high temperatures, which can lead to forming voids and unwanted open circuits at the contact interfaces. For example, experimentation and testing has shown that if ruthenium is used for the first metal via 61 and copper with cobalt liner is used for the second metal layer 82 without the first cap layer 111 (i.e., the ruthenium being in contact with the cobalt and/or copper), under heating at about 400ºC, the copper, cobalt, and ruthenium intermix and can form voids at the contact interface. For example, niobium can be used for the first cap layer 111 between a first metal via 61 of ruthenium, where the second metal layer 82 includes copper and/or cobalt.

Tests and experiments have shown that a first cap layer 111 containing niobium deposited using PVD, with a thickness in a range of 1 nm to 10 nm, on a first metal via 61 made of ruthenium has performed well to prevent, hinder, or significantly reduce intermixing of the ruthenium with cobalt, copper, or cobalt-copper combinations, for example. In some embodiments, a given first cap layer 111 made of a metal material can be selectively deposited on a first metal via 61 using chemical vapor deposition (CVD) or atomic layer deposition (ALD). For example, a thickness of a given first cap layer 111 including metal material(s) can be between about 1nm and about 10nm, between about 1nm and about 2nm, or between about 1nm and about 5nm.

Even though the first cap layer 111 is illustrated and represented in the drawings as a single layer of one material, in some embodiments, this first cap layer 111 can be a single layer of one material, a single layer of an alloy or mix of multiple materials, multiple layers of one material, multiple layers of a same alloy or mix of multiple materials, or multiple layers of different materials or alloy(s) of materials, for example. In some embodiments, the first cap layer 111 can include metal material(s) such as niobium, tungsten, tantalum, aluminum, alloys thereof, layers thereof, mixtures thereof, laminates thereof, or generally any combination thereof, for example. In some embodiments, the first cap layer 111 can be formed using physical vapor deposition (PVD), chemical vapor deposition (CVD), atomic layer deposition (ALD), or any combination thereof, for example. In some embodiments, the first cap layer 111 can be formed using a selective deposition technique.

For example, even when the material(s) of the first metal via 61 and the second metal layer 82 are the same, overlapping by some combination materials, or not susceptible to problems of intermixing and/or migration, a first cap layer 111 can be used for improving the conductivity at the connection interface between the first metal via 61 and the second metal layer 82. For example, with implementation of using ruthenium, molybdenum, tungsten, or any combination thereof, for the first metal via 61 and/or the second metal layer 82, experimentation and testing has shown that adding a graphene layer at the contact interface between the first metal via 61 and the second metal layer 82 can reduce the contact resistance and improve conductivity. Accordingly, in some embodiments, the first cap layer 111 can be or can include a graphene layer.

In some embodiments, a graphene layer for the first cap layer 111 can be formed using a suitable deposition process such as a chemical vapor deposition (CVD), plasma enhanced CVD (PECVD), atomic layer deposition (ALD), or plasma enhanced ALD (PEALD) process, with an appropriate graphene precursor. In some embodiments, a graphene layer for the first cap layer 111 can be formed using a layer transfer method.

In some embodiments, a graphene layer for the first cap layer 111 can be formed by chemical vapor deposition (CVD) for growing graphene. A gaseous precursor containing carbon can be introduced into a high-temperature reactor or chamber along with the wafer. The carbon atoms from the precursor can then react on the surface of the metal of the first metal via 61 to thereby form an initial sheet of graphene. A CVD process can be continued to build up, grow, or deposit additional sheets of graphene to increase a thickness of the resulting graphene layer. The temperature and gas composition can be used to control a quality and thickness of the graphene. In some embodiments, PECVD can be used as a variation of CVD to enhance the deposition process. Plasma can provide additional energy to facilitate the growth of high-quality graphene sheets.

In some embodiments, a graphene layer for the first cap layer 111 can be formed by liquid phase exfoliation, which can include breaking down graphite into individual graphene sheets using a solvent and then dispersing the graphene over the metal of the first metal via 61. Liquid phase exfoliation can be a scalable and relatively low-cost method of depositing graphene, but the results can be less controllable for layer uniformity compared to CVD.

In some embodiments, silicon carbide (SiC) can be converted to graphene by annealing the silicon carbide at high temperature to sublimate silicon atoms to leave behind a graphene layer. However, this conversion process can consume significant thermal budget.

In some embodiments, graphene can be epitaxially grown onto a surface having a similar crystal structure, but this process also can require high temperature and specific material properties for the metal of the first metal via 61 onto which the graphene is grown.

In some embodiments, a selective graphene deposition can be performed using a suitable selective deposition process, such as a chemical vapor deposition (CVD), plasma enhanced CVD (PECVD), atomic layer deposition (ALD), or plasma enhanced ALD (PEALD) process with an appropriate graphene precursor.

In some embodiments, the formation of the graphene can be performed using a vapor deposition process at a temperature in a range of 40°C to 150°C. The graphene can have a decomposition temperature range of 200°C to 350°C.

Prior to performing graphene deposition, graphene growth, or selective graphene deposition, an optional pretreatment can be performed to remove any surface oxide so that a surface of the metal of the first metal via 61 becomes accessible for subsequent process steps. In various embodiments, the optional pretreatment can be a wet process. In one example, an alcohol solution can be applied at room temperature for a set or selected time. The alcohol solution can include one or more alcohols or, alternatively, the alcohol solution can include one or more alcohols and a non-oxidizing solvent. The alcohol solution can contain any alcohol with a chemical formula R—OH. One class of alcohols is primary alcohols, of which methanol and ethanol are the simplest members. Another class of alcohols is secondary alcohols, for example isopropyl alcohol (IPA). In certain embodiments, the optional pretreatment can also include an operation or step to remove moisture from the intermediate structure (e.g., substrate and/or the metal of the first metal via). The removal of moisture can be performed, for example, by a thermal treatment under an inert gas flow. In certain embodiments, the optional pretreatment can include a dry process using one or more reducing gases with or without a plasma.

The choice of process(es) for forming graphene sheets for the graphene layer(s) for the first cap layer 111 can depend on factors such as a desired graphene quality, scalability, and specific requirements of a given semiconductor application. Each process of forming graphene has its advantages and challenges, and researchers are continually exploring new techniques to improve the deposition processes for graphene.

In various embodiments, the graphene layer(s) for the first cap layer 111 can include a single graphene sheet or several graphene sheets, and thus have a thickness of one to several atomic layers (e.g., less than 1 nm). The material properties of graphene such as superior electrical conductivity can make graphene an attractive alternative to form a capping layer compared to conventional metals. Further, the use of graphene can advantageously enable a very thin capping layer on the first metal via 61. In some embodiments, the graphene layer(s) for the first cap layer 111 can include several graphene sheets to form a thicker graphene layer with a thickness in a range of 5 nm to 10 nm, for example. Thus, in various embodiments, a graphene layer for the first cap layer 111 can have a thickness in a range of less than 1 nm (e.g., one sheet of graphene) to 10 nm (multiple sheets of graphene), for example.

In some embodiments, prior to subsequent deposition steps after forming a graphene layer, an optional post-graphene treatment, such as annealing, can be performed to remove impurities and/or improve a quality and structure of the deposited/grown graphene.

In some embodiments, the first cap layer 111 can include one or more metal layers (as described above) and one or more graphene layers (as described above), in any layering sequence.

Referring to FIG. 12-15, the process flow for forming the intermediate structures illustrated in FIGS. 12-15 can be the same as that shown in and described regarding FIGS. 3-8, except that the first cap layer 111 is present. Hence, the first SAM 71 can be selectively deposited directly on the first cap layer 111 rather than directly on the first metal via 61. Accordingly, the material and the deposition/formation process selected for the first SAM can depend on the top-most material or exposed material of the first cap layer 111, and the top-most material or exposed material of the first dielectric layer 51. The first SAM 71 can be selected to adhere to or bond to the first cap layer 111 substantially faster and/or stronger than to the first dielectric layer 51, thereby providing a selective deposition of the first SAM 71 on the first cap layer 111.

Example SAM materials for use with metal (e.g., where metal is a top-most material of the first cap layer 111) were described already above. An example of a head group for SAMs that can selectively form on a graphene surface (e.g., wherein graphene is a top-most material of the first cap layer 111) can include aryl diazonium salts (e.g., organic compounds containing a diazo group (N2) attached to an aromatic ring). Some example aryl diazonium salts that can be suitable for potential use in some embodiments can include: 4-Nitrobenzenediazonium Tetrafluoroborate; 4-Carboxybenzenediazonium Tetrafluoroborate (contains a carboxylic acid group (-COOH) that can attach to graphene via covalent bonding); 4-Aminobenzenediazonium Tetrafluoroborate (amino group (-NH2) that can react with graphene to form a covalent monolayer); 4-Mercaptobenzenediazonium Tetrafluoroborate (contains a thiol group (-SH) that can form strong covalent bonds with graphene, leading to the formation of a thiol-functionalized monolayer on the graphene surface); 4-Cyanobenzenediazonium Tetrafluoroborate (includes a cyano group (-CN) that can attach to graphene surfaces through covalent bonding); or any suitable combination thereof.

Some research and experimentation have shown that encasing or partially encasing a metal, such as ruthenium, molybdenum, or niobium, of a via, trench, and/or conducting line with a graphene layer can decrease line and/or contract resistance, and improve conductivity through such metals. Accordingly, FIG. 16 illustrates (in a simplified manner) an embodiment in which the metal of the first metal via 61 (at level M1 in this example) and the conducting lines 94 of the second metallization layer 92 (at level M2 in this example) are encased with graphene. For example, before depositing metal material in the first via hole 41 (see e.g., FIG. 1), a graphene layer can be formed, conformally, in the bottom and/or on the sides of the first via hole 41, and then the metal material can be formed on the graphene layer to form the first metal via 61. And in such example, the first cap layer 111 can include graphene. For example, after the etching and defining of the multiple distinct conducting lines 94 of the second metallization layer 92 (see e.g., FIG. 7), a graphene layer can be formed (e.g., conformally) over the conducting lines. And as described above, in some embodiments, the second dielectric layer 102 shown in FIG. 16 can be dissolved or evaporated during subsequent processing such that there are air gaps between the conducting lines 94.

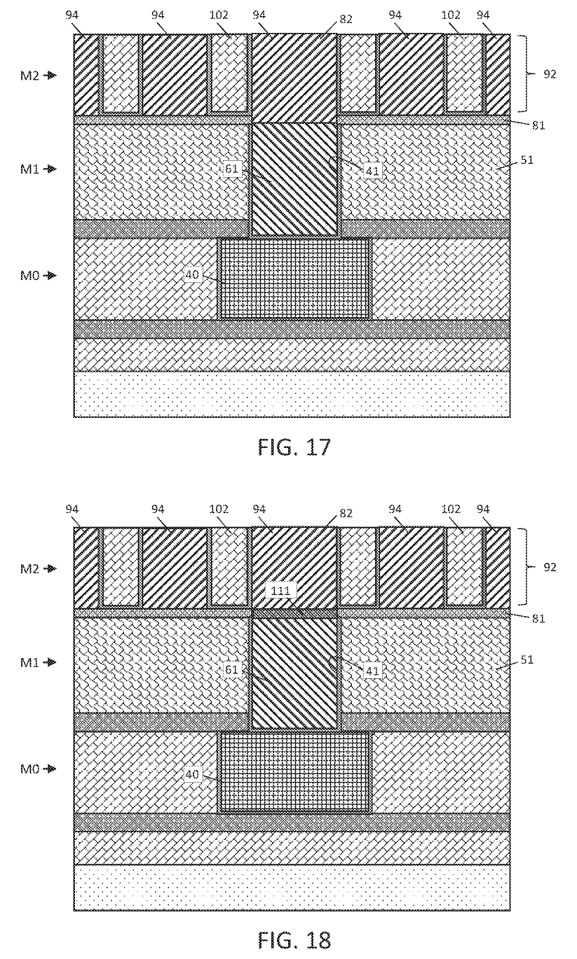

Referring to FIGS. 17 and 18, in some embodiments, it may be needed or desired to have a liner layer and/or barrier layer between the metal material of the first metal via 61 and the first dielectric layer 51 and/or the underlying metal contact 40. For example, before depositing metal material in the first via hole 41 (see e.g., FIG. 1), a liner layer and/or barrier layer can be formed, conformally, in the bottom and/or on the sides of the first via hole 41, and then the metal material can be formed on the liner layer and/or barrier layer. Still referring to FIGS. 17 and 18, in some embodiments it may be needed or desired to have a liner layer and/or barrier layer between the metal material of the conducting lines 94 of the second metallization layer 92 and the second dielectric layer 102. For example, after the etching and defining of the multiple distinct conducting lines 94 of the second metallization layer 92 (see e.g., FIG. 7), a liner layer and/or barrier layer can be formed (e.g., conformally) over the conducting lines 94. Even though some materials (e.g., ruthenium and molybdenum) do not require barrier layers like copper would, a liner layer (e.g., graphene) may be included to improve adhesion, improve conductivity, or some combination thereof.

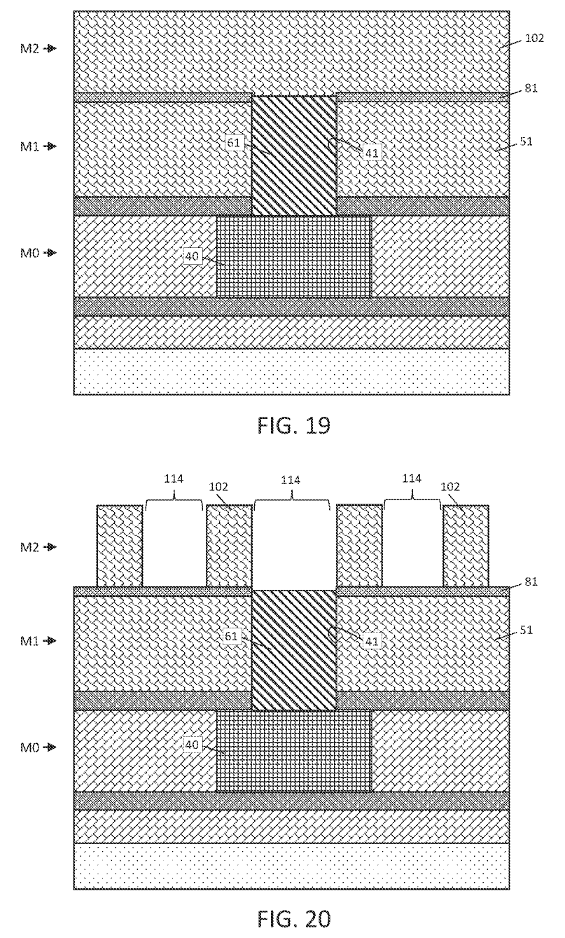

FIGS. 19 to 21 are cross-section views illustrating intermediate structures of a semiconductor device made using a method according to an embodiment of the present disclosure. Rather than first forming the second metal layer 82 and using subtractive etching of the second metal layer 82 to form the multiple distinct conducting lines 94 (see e.g., FIGS. 6-7), a second dielectric layer 102 can be first formed, patterned, and etched to define the trenches for the multiple distinct conducting lines 94, and then depositing the second metal layer 82 into those trenches, with the other operations of a method according to an embodiment of the present disclosure being the same up to the deposition of the second dielectric layer 102.

Accordingly, the process flow for forming the intermediate structures shown in and described regarding FIGS. 1-5 can be used leading up to the intermediate structure of FIG. 19. Referring to FIG. 19, a second dielectric layer 102 can be formed on the first metal via 61 and the first etch stop layer 81. Even though the second dielectric layer 102 is illustrated and represented in the drawings as a single layer of one material, in some embodiments, in some embodiments, the second dielectric layer can be a single layer of one material, a single layer of a mix of multiple materials, multiple layers of one material, multiple layers of a same material or mix of multiple materials, or multiple layers of different materials, for example.

Referring to FIG. 20, the second dielectric layer 102 can be patterned and etched to form trenches 114. The etching of the second dielectric layer 102 can stop on the first etch stop layer 81 (e.g., can open to the first etch stop layer 81). The etching of the second dielectric layer 102 can be selective to etch the second dielectric layer 102 faster than the first etch stop layer 81, which can help with fully opening up the bottoms of the trenches 114, as needed or per design/specifications. Photolithography and patterning masks can be used and removed between the intermediate structures of FIGS. 19 and 20, as can be apparent to one of ordinary skill in the art, and thus are not further described herein.

Without the first etch stop layer 81 being in place, there would be a much greater potential for damaging the first dielectric layer 51 (especially when it is a low-k dielectric material) or over etching into the first dielectric layer 51 while etching the second dielectric layer 102 at level M2. The first etch stop layer 81 can act as a stable structural platform or subfloor (uniformly supported by the underlying first dielectric layer) for the multiple distinct conducting lines 94, which can improve device reliability, process integration flow, manufacturing consistency/repeatability, and product yield.

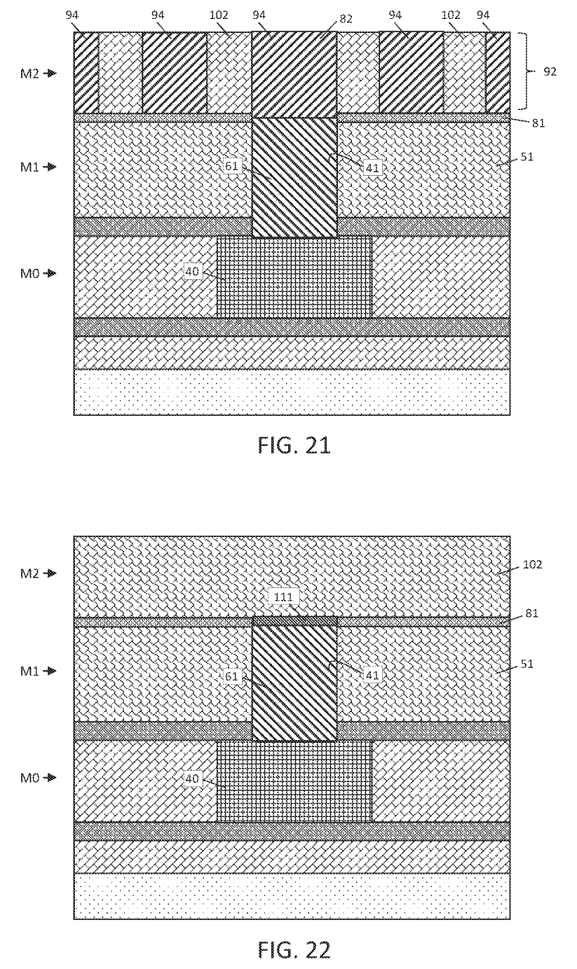

Referring to FIG. 21, a second metal layer 82 can be deposited in the trenches 114 to form a second metallization layer 92 including multiple distinct conducting lines 94. A planarization step (e.g., CMP) can be performed to remove excess metal of the second metal layer from the top surfaces of the second dielectric layer 102, for example.

Even though the second metal layer 82 is illustrated and represented in the drawings as a single layer of one material, in some embodiments, this second metal layer can be a single layer of one material, a single layer of an alloy or mix of multiple materials, multiple layers of one material, multiple layers of a same alloy or mix of multiple materials, or multiple layers of different materials or alloy(s) of materials, for example. In some embodiments, the second metal layer 82 can be a different material than the first metal via 61. In some embodiments, the second metal layer 82 can be a same material as the first metal via 61.

In a completed structure of the semiconductor device made according to an embodiment of the present disclosure, portions of the first etch stop layer 81 can be removed (e.g., over etching while etching the second dielectric layer 102) in some places, and portions of the first etch stop layer 81 may remain (e.g., between the first dielectric layer 51 and the second metallization layer 92).

FIGS. 22 to 24 are cross-section views illustrating intermediate structures of a semiconductor device made using a method according to an embodiment of the present disclosure. The process flow for forming the intermediate structures illustrated in FIGS. 22-24 can be the same as that shown in and described regarding FIGS. 19-21, except that the first cap layer 111 is present. Hence, the first SAM 71 can be selectively deposited directly on the first cap layer 111 rather than directly on the first metal via 61.

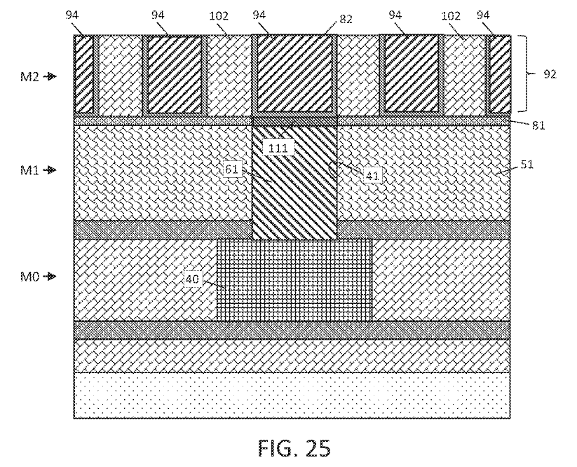

FIG. 25 illustrates a variation on the method illustrated in FIGS. 22-24, wherein a barrier layer and/or liner layer is conformally formed in the trenches prior to forming the second metal layer 82 (e.g., copper, cobalt, or some combination thereof).

Adding to the height of the via hole or trench by the mask(s) or hard mask remaining in place can greatly increase the challenge of achieving a non-voided via fill. Thus, an advantage of using a method embodiment of the present disclosure in which the mask or masks are removed from a top surface of the first dielectric material after the via holes or trenches are patterned and etched, and before the deposition of conductive material(s) and/or liner(s) in the via holes or trenches, provides a way to minimize the aspect ratio during the deposition of conductive material(s) and/or liner(s) in the via holes or trenches, as well as reducing the amount of filling depth to form the first metal via (i.e., having less material filling depth reduces risk of forming voids in the first metal via). Because a subsequent etch stop layer will be formed (making use of SAM for a blocking layer) to subsequently protect the first dielectric layer with that etch stop layer, it can be possible to remove the hard mask to reduce the aspect ratio for filling the via holes or trenches.

Although the example embodiments of the present disclosure show and discuss a via hole filled with via metal for illustrating method embodiments, in other embodiments the via hole can be substituted with a trench or dual damascene (trench and via hole combination), as can be apparent to one of ordinary skill in the art. Thus, the term “via hole” used herein can be interpreted more broadly so that the appended claims can also cover other equivalent structures (e.g., trench and/or trench-via-hole combination) making use of a method embodiment of the present disclosure.

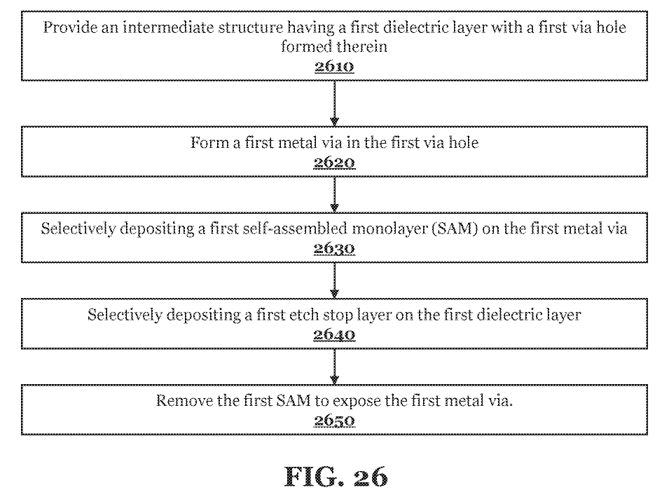

FIG. 26 illustrates a flow chart implementing an etch stop layer using a SAM as a blocking layer in accordance with an embodiment of the present disclosure. In an embodiment, a method for making a semiconductor device includes providing an intermediate structure including a first dielectric layer, the first dielectric layer having a first via hole formed therein, where the first via hole opens to an underlying metal contact (box 2610). The method includes forming a first metal via in the first via hole (box 2620). The method includes selectively depositing a first self-assembled monolayer (SAM) on the first metal via (box 2630). The method includes selectively depositing a first etch stop layer on the first dielectric layer (box 2640). The method includes removing the first SAM to expose the first metal via (box 2650).

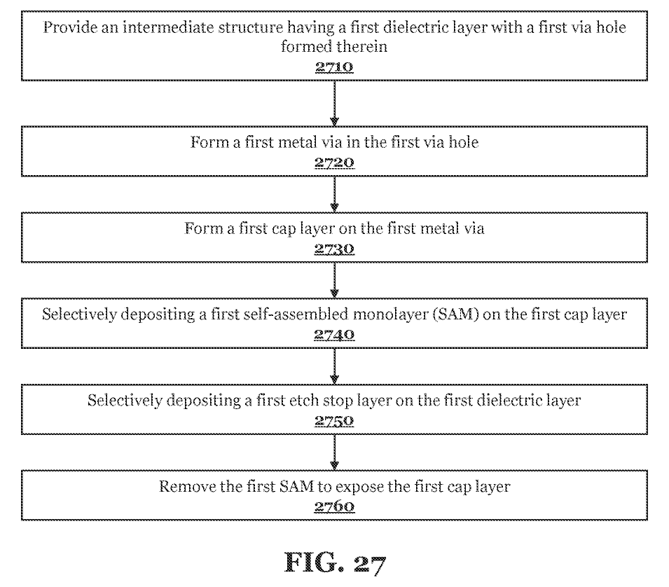

FIG. 27 illustrates a flow chart implementing an etch stop layer using a SAM as a blocking layer in accordance with an embodiment of the present disclosure. In an embodiment, a method for making a semiconductor device includes providing an intermediate structure including a first dielectric layer, the first dielectric layer having a first via hole formed therein, wherein the first via hole opens to an underlying metal contact (box 2710). The method includes forming a first metal via in the first via hole (box 2720). The method includes forming a first cap layer on the first metal via (box 2730). The method includes selectively depositing a first self-assembled monolayer (SAM) on the first cap layer (box 2740). The method includes selectively depositing a first etch stop layer on the first dielectric layer (box 2750). The method includes removing the first SAM to expose the first cap layer (box 2760).

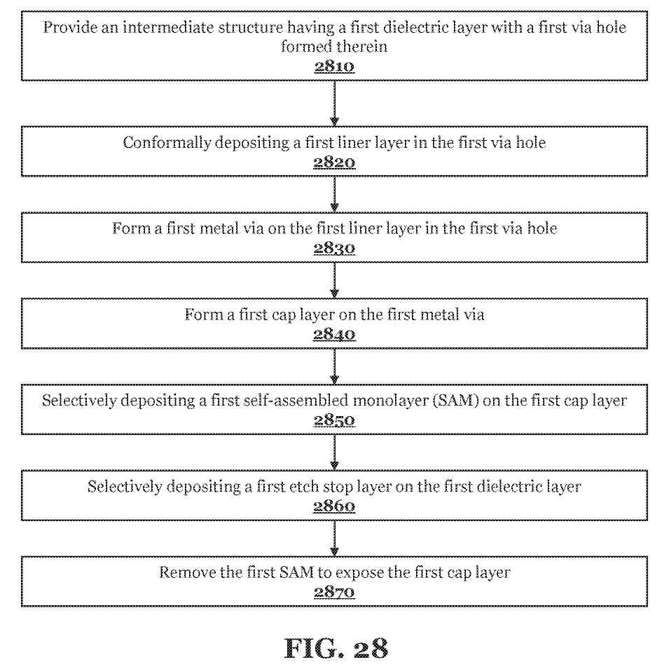

FIG. 28 illustrates a flow chart implementing an etch stop layer using a SAM as a blocking layer in accordance with an embodiment of the present disclosure. In an embodiment, a method for making a semiconductor device includes providing an intermediate structure including a first dielectric layer, the first dielectric layer having a first via hole formed therein, wherein the first via hole opens to an underlying metal contact (box 2810). The method includes conformally depositing a first liner layer in the first via hole (box 2820). The method includes forming a first metal via on the first liner layer in the first via hole (box 2830). The method includes forming a first cap layer on the first metal via (box 2840). The method includes selectively depositing a first self-assembled monolayer (SAM) on the first cap layer (box 2850). The method includes selectively depositing a first etch stop layer on the first dielectric layer (box 2860). The method includes removing the first SAM to expose the first cap layer (box 2870).

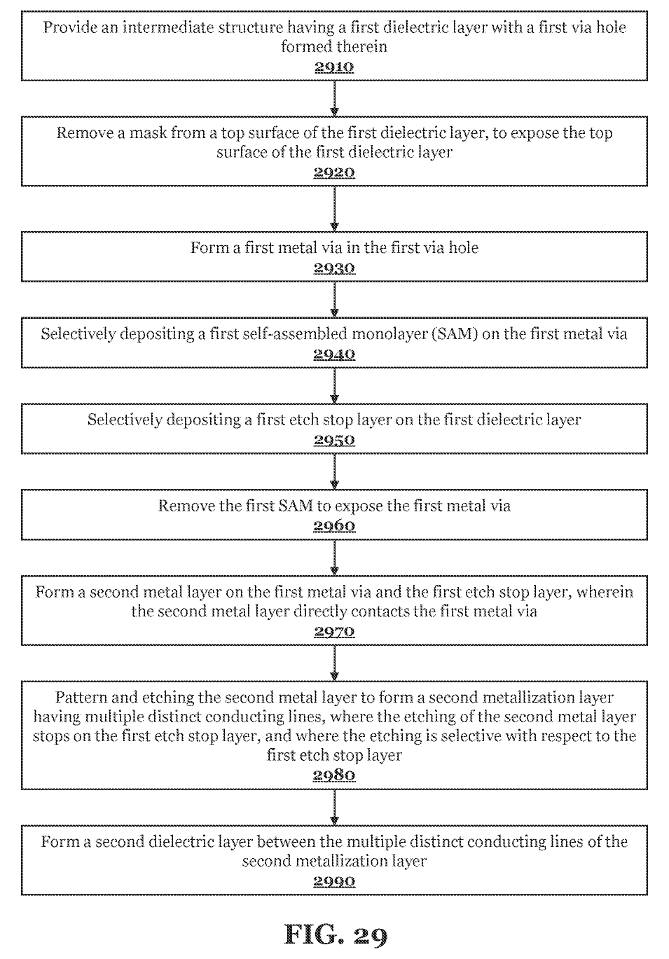

FIG. 29 illustrates a flow chart implementing an etch stop layer using a SAM as a blocking layer in accordance with an embodiment of the present disclosure. In an embodiment, a method for making a semiconductor device includes providing an intermediate structure including a first dielectric layer, the first dielectric layer having a first via hole formed therein, wherein the first via hole opens to an underlying metal contact (box 2910). The method includes removing a mask from a top surface of the first dielectric layer, to expose the top surface of the first dielectric layer (box 2920). The method includes forming a first metal via in the first via hole (box 2930). The method includes selectively depositing a first self-assembled monolayer (SAM) on the first metal via (box 2940). The method includes selectively depositing a first etch stop layer on the first dielectric layer (box 2950). The method includes removing the first SAM to expose the first metal via (box 2960). The method includes forming a second metal layer on the first metal via and the first etch stop layer, where the second metal layer directly contacts the first metal via (box 2970). The method includes patterning and etching the second metal layer to form a second metallization layer having multiple distinct conducting lines, where the etching of the second metal layer stops on the first etch stop layer, and where the etching is selective with respect to the first etch stop layer (box 2980). The method includes forming a second dielectric layer between the multiple distinct conducting lines of the second metallization layer (box 2990).

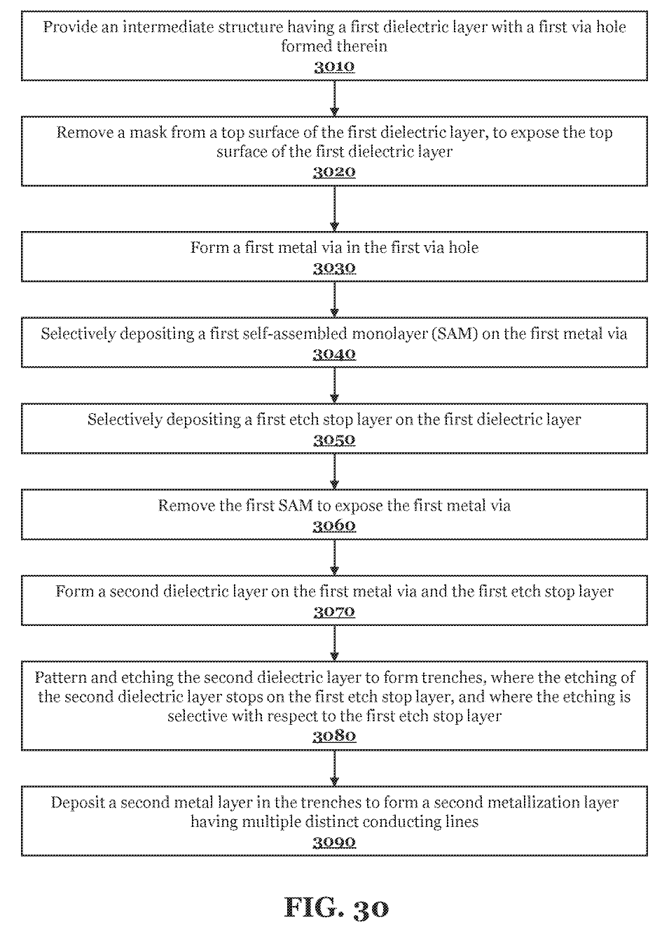

FIG. 30 illustrates a flow chart implementing an etch stop layer using a SAM as a blocking layer in accordance with an embodiment of the present disclosure. In an embodiment, a method for making a semiconductor device includes providing an intermediate structure including a first dielectric layer, the first dielectric layer having a first via hole formed therein, wherein the first via hole opens to an underlying metal contact (box 3010). The method includes removing a mask from a top surface of the first dielectric layer, to expose the top surface of the first dielectric layer (box 3020). The method includes forming a first metal via in the first via hole (box 3030). The method includes selectively depositing a first self-assembled monolayer (SAM) on the first metal via (box 3040). The method includes selectively depositing a first etch stop layer on the first dielectric layer (box 3050). The method includes removing the first SAM to expose the first metal via (box 3060). The method includes forming a second dielectric layer on the first metal via and the first etch stop layer (box 3070). The method includes patterning and etching the second dielectric layer to form trenches, where the etching of the second dielectric layer stops on the first etch stop layer, and where the etching is selective with respect to the first etch stop layer (box 3080). The method includes depositing a second metal layer in the trenches to form a second metallization layer having multiple distinct conducting lines (box 3090).

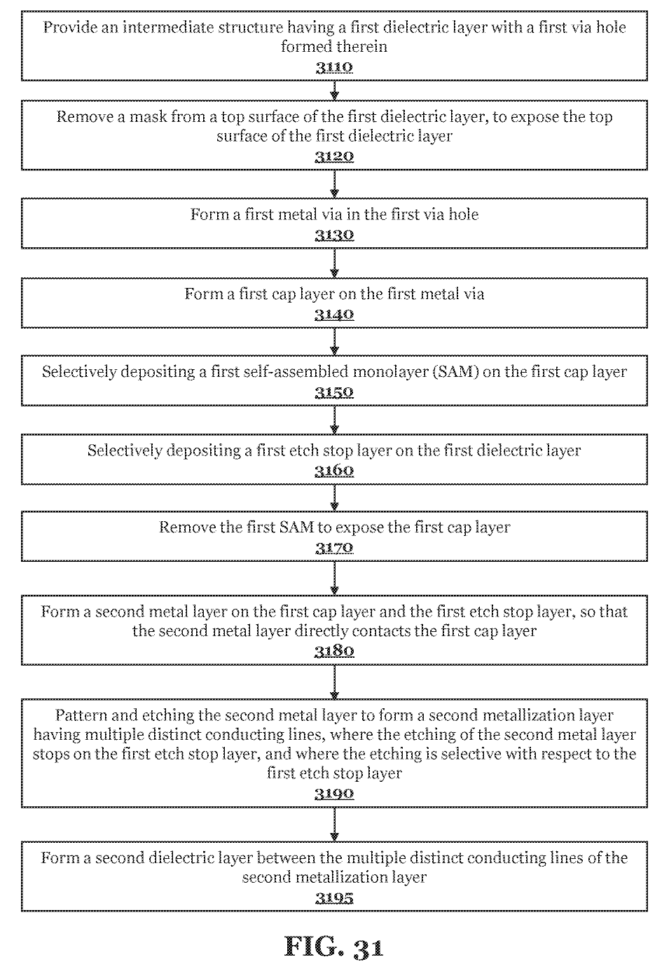

FIG. 31 illustrates a flow chart implementing an etch stop layer using a SAM as a blocking layer in accordance with an embodiment of the present disclosure. In an embodiment, a method for making a semiconductor device includes providing an intermediate structure including a first dielectric layer, the first dielectric layer having a first via hole formed therein, wherein the first via hole opens to an underlying metal contact (box 3110). The method includes removing a mask from a top surface of the first dielectric layer, to expose the top surface of the first dielectric layer (box 3120). The method includes forming a first metal via in the first via hole (box 3130). The method includes forming a first cap layer on the first metal via (box 3140). The method includes selectively depositing a first self-assembled monolayer (SAM) on the first cap layer (box 3150). The method includes selectively depositing a first etch stop layer on the first dielectric layer (box 3160). The method includes removing the first SAM to expose the first cap layer (box 3170). The method includes forming a second metal layer on the first cap layer and the first etch stop layer, so that the second metal layer directly contacts the first cap layer (box 3180). The method includes patterning and etching the second metal layer to form a second metallization layer having multiple distinct conducting lines, where the etching of the second metal layer stops on the first etch stop layer, and where the etching is selective with respect to the first etch stop layer (box 3190). The method includes forming a second dielectric layer between the multiple distinct conducting lines of the second metallization layer (box 3195).

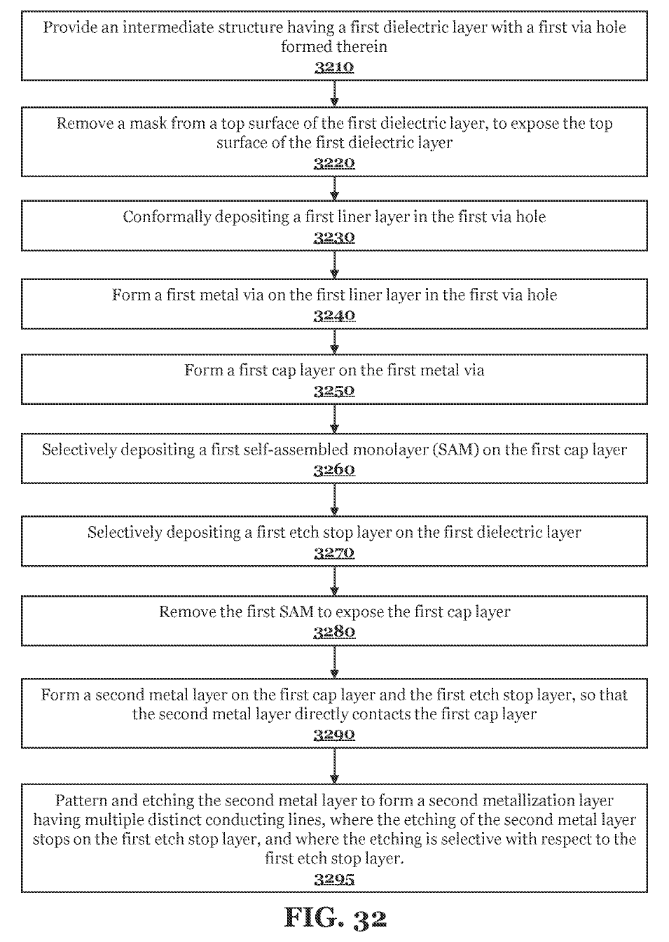

FIG. 32 illustrates a flow chart implementing an etch stop layer using a SAM as a blocking layer in accordance with an embodiment of the present disclosure. In an embodiment, a method for making a semiconductor device includes providing an intermediate structure including a first dielectric layer, the first dielectric layer having a first via hole formed therein, wherein the first via hole opens to an underlying metal contact (box 3210). The method includes removing a mask from a top surface of the first dielectric layer, to expose the top surface of the first dielectric layer (box 3220). The method includes conformally depositing a first liner layer in the first via hole (box 3230). The method includes forming a first metal via on the first liner layer in the first via hole (box 3240). The method includes forming a first cap layer on the first metal via (box 3250). The method includes selectively depositing a first self-assembled monolayer (SAM) on the first cap layer (box 3260). The method includes selectively depositing a first etch stop layer on the first dielectric layer (box 3270). The method includes removing the first SAM to expose the first cap layer (box 3280). The method includes forming a second metal layer on the first cap layer and the first etch stop layer, so that the second metal layer directly contacts the first cap layer (box 3290). The method includes patterning and etching the second metal layer to form a second metallization layer having multiple distinct conducting lines, where the etching of the second metal layer stops on the first etch stop layer, and where the etching is selective with respect to the first etch stop layer (box 3295).

The embodiments described in FIGS. 26-32 may be implemented as further described using FIGS. 1-25.

More example embodiments of the present disclosure are summarized here. Other embodiments can also be understood from the entirety of the specification as well as the claims filed herein.

Example 1. A method for making a semiconductor device, the method including providing an intermediate structure including a first dielectric layer, the first dielectric layer having a first via hole formed therein, where the first via hole opens to an underlying metal contact, forming a first metal via in the first via hole, selectively depositing a first self-assembled monolayer (SAM) on the first metal via, selectively depositing a first etch stop layer on the first dielectric layer, and removing the first SAM to expose the first metal via.

Example 2. The method of example 1, further including removing a mask from a top surface of the first dielectric layer, to expose the top surface of the first dielectric layer, prior to the forming of the first metal via.

Example 3. The method of one of examples 1 or 2, further including forming a second metal layer on the first metal via and the first etch stop layer, where the second metal layer directly contacts the first metal via, and patterning and etching the second metal layer to form a second metallization layer including multiple distinct conducting lines, where the etching of the second metal layer stops on the first etch stop layer, and where the etching is selective with respect to the first etch stop layer.

Example 4. The method of one of examples 1 to 3, further including forming a second dielectric layer between the multiple distinct conducting lines of the second metallization layer.

Example 5. The method of one of examples 1 to 4, where the second metal layer includes a different metal material than the first metal via.

Example 6. The method of one of examples 1 to 5, where the second metal layer includes a same metal material as the first metal via.

Example 7. The method of one of examples 1 to 6, where the forming of the first metal via includes overfilling the first via hole and covering at least part of the first dielectric layer, and planarizing a top surface to expose the first dielectric layer.

Example 8. The method of one of examples 1 to 7, further including forming a second dielectric layer on the first metal via and the first etch stop layer, and patterning and etching the second dielectric layer to form trenches, where the etching of the second dielectric layer stops on the first etch stop layer, and where the etching is selective with respect to the first etch stop layer, and depositing a second metal layer in the trenches to form a second metallization layer including multiple distinct conducting lines.

Example 9. The method of one of examples 1 to 8, further including forming a second dielectric layer on the first metal via and the first etch stop layer, and patterning and etching the second dielectric layer to form trenches, where the etching of the second dielectric layer stops on the first etch stop layer, and where the etching is selective with respect to the first etch stop layer, conformally depositing a barrier layer in the trenches, and depositing a second metal layer on the barrier layer in the trenches to form a second metallization layer including multiple distinct conducting lines.

Example 10. A method for making a semiconductor device, the method including providing an intermediate structure including a first dielectric layer, the first dielectric layer having a first via hole formed therein, where the first via hole opens to an underlying metal contact, forming a first metal via in the first via hole, forming a first cap layer on the first metal via, selectively depositing a first self-assembled monolayer (SAM) on the first cap layer, selectively depositing a first etch stop layer on the first dielectric layer, and removing the first SAM to expose the first cap layer.

Example 11. The method of example 10, further including removing a mask from a top surface of the first dielectric layer, to expose the top surface of the first dielectric layer, prior to the forming of the first metal via.

Example 12. The method of one of examples 10 or 11, further including forming a second metal layer on the first cap layer and the first etch stop layer, where the second metal layer directly contacts the first cap layer, and patterning and etching the second metal layer to form a second metallization layer including multiple distinct conducting lines, where the etching of the second metal layer stops on the first etch stop layer, and where the etching is selective with respect to the first etch stop layer.

Example 13. The method of one of examples 10 to 12, further including forming a second dielectric layer between the multiple distinct conducting lines of the second metallization layer.

Example 14. The method of one of examples 10 to 13, where the first cap layer includes a metal cap layer.

Example 15. The method of one of examples 10 to 14, where the first cap layer includes a graphene layer.

Example 16. A method for making a semiconductor device, the method including providing an intermediate structure including a first dielectric layer, the first dielectric layer having a first via hole formed therein, where the first via hole opens to an underlying metal contact, conformally depositing a first liner layer in the first via hole, forming a first metal via on the first liner layer in the first via hole, forming a first cap layer on the first metal via, selectively depositing a first self-assembled monolayer (SAM) on the first cap layer, selectively depositing a first etch stop layer on the first dielectric layer, and removing the first SAM to expose the first cap layer.

Example 17. The method of example 16, further including removing a mask from a top surface of the first dielectric layer, to expose the top surface of the first dielectric layer, prior to the forming of the first metal via.

Example 18. The method of one of examples 16 or 17, further including forming a second metal layer on the first cap layer and the first etch stop layer, where the second metal layer directly contacts the first cap layer, and patterning and etching the second metal layer to form a second metallization layer including multiple distinct conducting lines, where the etching of the second metal layer stops on the first etch stop layer, and where the etching is selective with respect to the first etch stop layer.

Example 19. The method of one of examples 16 to 18, where the first liner layer includes a first graphene layer, and where the first cap layer includes a second graphene layer.

Example 20. The method of one of examples 16 to 19, where the first liner layer includes a first barrier layer, and where the first cap layer includes a metal cap layer.

While illustrative and example embodiments have been described with reference to illustrative drawings, this description is not intended to be construed in a limiting sense. Various modifications and combinations of the illustrative and example embodiments, as well as other embodiments, can be apparent to persons skilled in the pertinent art upon referencing the present disclosure. It is therefore intended that the appended claims encompass any and all of such modifications, equivalents, or embodiments.

What is claimed is:

1. A method for making a semiconductor device, the method comprising:
providing an intermediate structure comprising a first dielectric layer, the first dielectric layer having a first via hole formed therein, wherein the first via hole opens to an underlying metal contact;
forming a first metal via in the first via hole;
selectively depositing a first self-assembled monolayer (SAM) on the first metal via;
selectively depositing a first etch stop layer on the first dielectric layer; and
removing the first SAM to expose the first metal via.

2. The method of claim 1, further comprising removing a mask from a top surface of the first dielectric layer, to expose the top surface of the first dielectric layer, prior to the forming of the first metal via.

3. The method of claim 1, further comprising:
forming a second metal layer on the first metal via and the first etch stop layer, wherein the second metal layer directly contacts the first metal via; and
patterning and etching the second metal layer to form a second metallization layer comprising multiple distinct conducting lines, wherein the etching of the second metal layer stops on the first etch stop layer, and wherein the etching is selective with respect to the first etch stop layer.

4. The method of claim 3, further comprising forming a second dielectric layer between the multiple distinct conducting lines of the second metallization layer.

5. The method of claim 3, wherein the second metal layer comprises a different metal material than the first metal via.

6. The method of claim 3, wherein the second metal layer comprises a same metal material as the first metal via.

7. The method of claim 1, wherein the forming of the first metal via comprises:
overfilling the first via hole and covering at least part of the first dielectric layer; and
planarizing a top surface to expose the first dielectric layer.

8. The method of claim 1, further comprising:
forming a second dielectric layer on the first metal via and the first etch stop layer; and
patterning and etching the second dielectric layer to form trenches, wherein the etching of the second dielectric layer stops on the first etch stop layer, and wherein the etching is selective with respect to the first etch stop layer; and
depositing a second metal layer in the trenches to form a second metallization layer comprising multiple distinct conducting lines.

9. The method of claim 1, further comprising:
forming a second dielectric layer on the first metal via and the first etch stop layer; and
patterning and etching the second dielectric layer to form trenches, wherein the etching of the second dielectric layer stops on the first etch stop layer, and wherein the etching is selective with respect to the first etch stop layer;
conformally depositing a barrier layer in the trenches; and
depositing a second metal layer on the barrier layer in the trenches to form a second metallization layer comprising multiple distinct conducting lines.

10. A method for making a semiconductor device, the method comprising:
providing an intermediate structure comprising a first dielectric layer, the first dielectric layer having a first via hole formed therein, wherein the first via hole opens to an underlying metal contact;
forming a first metal via in the first via hole;
forming a first cap layer on the first metal via;
selectively depositing a first self-assembled monolayer (SAM) on the first cap layer;
selectively depositing a first etch stop layer on the first dielectric layer; and
removing the first SAM to expose the first cap layer.

11. The method of claim 10, further comprising removing a mask from a top surface of the first dielectric layer, to expose the top surface of the first dielectric layer, prior to the forming of the first metal via.

12. The method of claim 10, further comprising:
forming a second metal layer on the first cap layer and the first etch stop layer, wherein the second metal layer directly contacts the first cap layer; and
patterning and etching the second metal layer to form a second metallization layer comprising multiple distinct conducting lines, wherein the etching of the second metal layer stops on the first etch stop layer, and wherein the etching is selective with respect to the first etch stop layer.

13. The method of claim 12, further comprising forming a second dielectric layer between the multiple distinct conducting lines of the second metallization layer.

14. The method of claim 10, wherein the first cap layer comprises a metal cap layer.

15. The method of claim 10, wherein the first cap layer comprises a graphene layer.

16. A method for making a semiconductor device, the method comprising:
providing an intermediate structure comprising a first dielectric layer, the first dielectric layer having a first via hole formed therein, wherein the first via hole opens to an underlying metal contact;
conformally depositing a first liner layer in the first via hole;
forming a first metal via on the first liner layer in the first via hole;
forming a first cap layer on the first metal via;
selectively depositing a first self-assembled monolayer (SAM) on the first cap layer;
selectively depositing a first etch stop layer on the first dielectric layer; and
removing the first SAM to expose the first cap layer.

17. The method of claim 16, further comprising removing a mask from a top surface of the first dielectric layer, to expose the top surface of the first dielectric layer, prior to the forming of the first metal via.

18. The method of claim 16, further comprising:
forming a second metal layer on the first cap layer and the first etch stop layer, wherein the second metal layer directly contacts the first cap layer; and
patterning and etching the second metal layer to form a second metallization layer comprising multiple distinct conducting lines, wherein the etching of the second metal layer stops on the first etch stop layer, and wherein the etching is selective with respect to the first etch stop layer.

19. The method of claim 16, wherein the first liner layer comprises a first graphene layer, and wherein the first cap layer comprises a second graphene layer.

20. The method of claim 16, wherein the first liner layer comprises a first barrier layer, and wherein the first cap layer comprises a metal cap layer.
